(19) United States
(12) Patent Application Publication
(10) Pub. No.: US 2015/0348836 A1
(43) Pub. Date: Dec. 3, 2015

(54) METHODS FOR DEPOSITING METAL ON A REACTIVE METAL FILM

(71) Applicant: APPLIED Materials, Inc., Santa Clara, CA (US)

(72) Inventors: Roey Shaviv, Palo Alto, CA (US); Ismail T. Emesh, Sunnyvale, CA (US)

(73) Assignee: APPLIED MATERIALS, INC., Santa Clara, CA (US)

(21) Appl. No.: 14/292,426

(22) Filed: May 30, 2014

(51) Int. Cl. H01L 21/768; H01L 23/532

(52) U.S. Cl. CPC H01L 21/76871; H01L 23/53209

(57) ABSTRACT

In accordance with one embodiment of the present disclosure, a method for depositing metal on a reactive metal film on a workpiece includes obtaining a workpiece including a dielectric surface; forming a barrier layer on the dielectric surface; depositing a seed layer on the barrier layer, wherein the barrier and seed stack includes at least one metal having a negative standard electrode potential; and depositing a metallization layer on the seed layer using a bath having a pH range of about 6 to about 11 and a current density in the range of about 1 mA/cm2 to about 5 mA/cm2.

### SUMMARY

Embodiments of the present disclosure are directed to methods for depositing metal on a reactive film and workpieces including reactive metal films. This summary is provided to introduce a selection of concepts in a simplified form that are further described below in the Detailed Description. This summary is not intended to identify key features of the claimed subject matter, nor is this summary intended to be used as an aid in determining the scope of the claimed subject matter.

In accordance with one embodiment of the present disclosure, a method for electrochemically depositing metal on a reactive metal film on a workpiece is provided. The method includes obtaining a workpiece including a dielectric surface; forming a barrier layer on the dielectric surface; depositing a seed layer on the barrier layer, wherein the barrier and seed stack includes at least one metal having a standard electrode potential of less than 0.34 V; and depositing a metallization layer on the seed layer using a bath having a pH range of about 6 to about 11 and a current density in the range of about 1 mA/cm2 to about 5 mA/cm2.

In accordance with one embodiment of the present disclosure, a method for electrochemically depositing metal on a reactive metal film on a workpiece is provided. The method includes obtaining a workpiece including a dielectric surface; forming a barrier layer on the dielectric surface, wherein the barrier layer includes manganese; depositing a seed layer on the barrier layer, wherein the barrier and seed stack includes at least one metal having a standard electrode potential of less than −0.25 V; and electrochemically depositing a metallization layer on the seed layer using a bath having a pH range of about 6 to about 11 and a current density in the range of about 1 mA/cm2 to about 5 mA/cm2.

In accordance with another embodiment of the present disclosure, a microfeature workpiece is provided. The workpiece a barrier layer on the dielectric surface having a thickness in the range of about 1.0 to about 2.3 nm, wherein the barrier layer includes manganese; a copper seed layer on the barrier layer having a thickness in the range of about 50 A to 300 A, wherein the barrier and seed stack includes at least one metal having a standard electrode potential of less than 0.34 V; and a metal layer on the seed layer.

In any of the embodiments described herein, the electrical potential of the workpiece during deposition of the metallization layer may be in the range of about −0.5 V to about −4 V.

In any of the embodiments described herein, the barrier and seed stack may include at least one metal having a standard electrode potential of less than 0 V.

In any of the embodiments described herein, the barrier and seed stack may include at least one metal having a standard electrode potential of less than −0.25 V.

In any of the embodiments described herein, the barrier layer may include manganese.

In any of the embodiments described herein, the barrier layer may be formed by depositing a compound selected from the group consisting of manganese and manganese nitride on a silicon oxide layer.

In any of the embodiments described herein, the barrier layer may be a manganese silicate layer.

In any of the embodiments described herein, one compound that makes up the barrier layer may be deposited by chemical vapor deposition or atomic layer deposition.

In any of the embodiments described herein, metal for the seed layer may be selected from the group consisting of copper, cobalt, nickel, gold, silver, manganese, tin, aluminum, ruthenium, and alloys thereof.

In any of the embodiments described herein, the seed layer may be deposited by chemical vapor deposition, physical vapor deposition, atomic layer deposition, or electroless deposition.

In any of the embodiments described herein, metal for the metallization layer may be selected from the group consisting of copper, cobalt, nickel, gold, silver, manganese, tin, aluminum, and alloys thereof.

In any of the embodiments described herein, the metallization layer may be deposited electrochemically.

In any of the embodiments described herein, the metallization layer may be deposited electrolessly.

In any of the embodiments described herein, the seed layer may be a metal seed layer deposited using a chemistry including at least one metal complex selected from the group consisting of ethylenediamine, citrate, tartrate, and urea.

### DESCRIPTION OF THE DRAWINGS

The foregoing aspects and many of the attendant advantages of this disclosure will become more readily appreciated by reference to the following detailed description, when taken in conjunction with the accompanying drawings, wherein:

FIGS. 1-3 are a series of schematic diagrams depicting a process and an exemplary feature development of an exemplary embodiment of the present disclosure;

FIGS. 4-6 are a series of schematic diagrams depicting a process and an exemplary feature development of another exemplary embodiment of the present disclosure;

FIG. 7 is a corrosion diagram for a CU/MnN stack film;

FIG. 8 is a graphical representation of linear sweep voltammetries is provided for various baths: conventional concentrated ECD copper acid chemistry without additives and with additives, and diluted ECD copper acid chemistry without additive and with additives;

FIG. 9 is a graphical representation of MnN dissolution versus current for conventional ECD copper acid chemistry and dilute ECD copper acid chemistry;

FIG. 10 is an SEM image of a feature deposited using previously designed methods; and

FIGS. 11 and 12 are SEM images of features deposited using methods in accordance with embodiments of the present disclosure.

### DETAILED DESCRIPTION

Embodiments of the present disclosure are directed to workpieces, such as semiconductor wafers, devices or processing assemblies for processing workpieces, and methods of processing the same. The term workpiece, wafer, or semiconductor wafer means any flat media or article, including semiconductor wafers and other substrates or wafers, glass, mask, and optical or memory media, MEMS substrates, or any other workpiece having micro-electric, micro-mechanical, or microelectro-mechanical devices. Embodiments of the present disclosure are directed to plating chemistries and methods of plating use to reduce the dissolution of a reactive metal barrier and seed stack film, such as a manganese-based barrier and a copper seed stack film.

Processes described herein are to be used for metal or metal alloy deposition in features of workpieces, which include trenches and vias. In one embodiment of the present disclosure, the process may be used in small features, for example, features having a feature diameter of less than 30 nm. However, the processes described herein may be applicable to any feature size. The dimension sizes discussed in the present application are post-etch feature dimensions at the top opening of the feature. The processes described herein may be applied to various forms of copper, cobalt, nickel, gold, silver, manganese, tin, aluminum, and alloy deposition, for example, in Damascene applications. In embodiments of the present disclosure, Damascene features may be selected from the group consisting of features having a feature diameter of less than 30 nm, about 5 to less than 30 nm, about 10 to less than 30 nm, about 15 to about 20 nm, about 20 to less than 30 nm, less than 20 nm, less than 10 nm, and about 5 to about 10 nm.

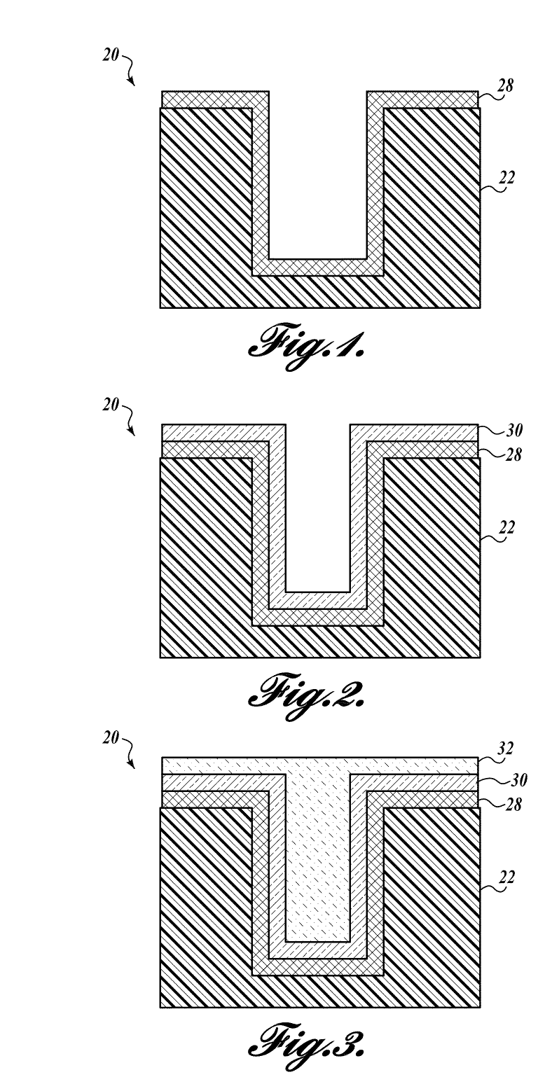

The descriptive terms “micro-feature workpiece” and “workpiece” as used herein include all structures and layers that have been previously deposited and formed at a given point in the processing, and is not limited to just those structures and layers as depicted in FIGS. 1-6.

Processes described herein may also be modified for metal or metal alloy deposition in high aspect ratio features, for example, vias in through silicon via (TSV) features.

Although generally described as metal deposition in the present application, the term “metal” also contemplates metal alloys and co-deposited metals. Such metals, metal alloys and co-deposited metals may be used to form seed layers or to fully or partially fill the feature. Exemplary co-deposited metals and copper alloys may include, but are not limited to, copper manganese and copper aluminum. As a non-limiting example in co-deposited metals and metal alloys, the alloy composition ratio may be in the range of about 0.5% to about 6% secondary alloy metal, as compared to the primary alloy metal (e.g., Cu, Co, Ni, Ag, Au, etc.).

An integrated circuit is an interconnected ensemble of devices formed within a semiconductor material and within a dielectric material that overlies a surface of the semiconductor material. Devices which may be formed within the semiconductor include transistors, bipolar transistors, diodes, and diffused resistors. Devices which may be formed within the dielectric include thin film resistors and capacitors. The devices are interconnected by conductor paths formed within the dielectric. Typically, two or more levels of conductor paths, with successive levels separated by a dielectric layer, are employed as interconnections. In current practice, copper and silica are commonly used for, respectively, the conductor and the dielectric.

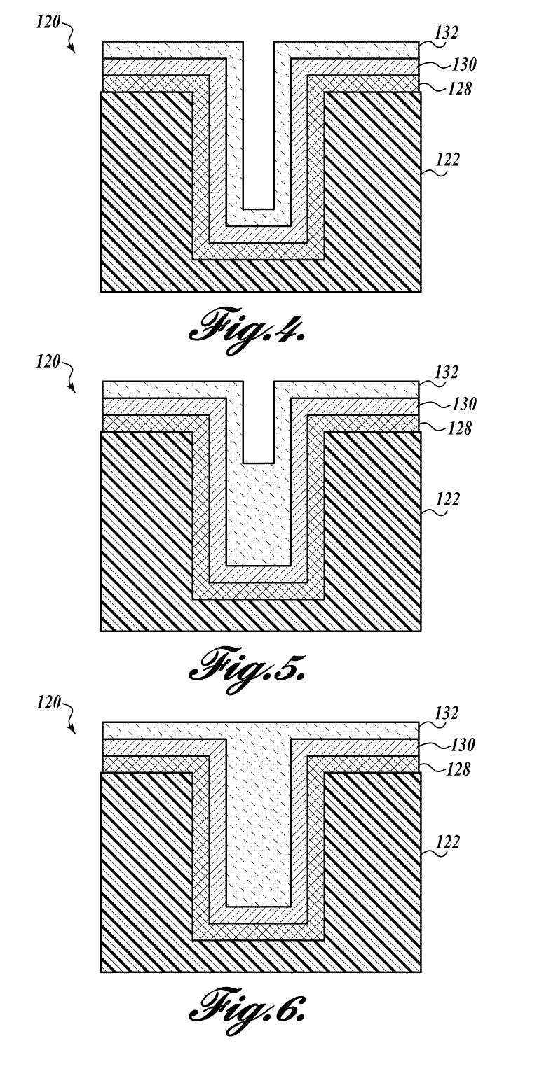

With reference to FIGS. 1-3, a process for forming an exemplary copper interconnect will now be described. As a non-limiting example, the series of deposits in a copper interconnect 20 typically include a dielectric layer 22, deposition of a barrier layer 28 (see FIG. 1), deposition of a seed layer 30 (see FIG. 2), copper fill 32 (see FIG. 3), and a copper cap.

Because copper tends to diffuse into the dielectric material, a barrier layer is used to isolate the copper deposit from the dielectric material. Barrier layers are typically made of refractory metals or refractory compounds, for example, titanium (Ti), tantalum (Ta), titanium nitride (TiN), tantalum nitride (TaN), etc. In recent years, Mn-based barrier layer materials have been explored, such as manganese (Mn) and manganese nitride (MnN). The barrier layer is typically formed using a deposition technique called physical vapor deposition (PVD), but can be formed by using other deposition techniques, such as chemical vapor deposition (CVD), atomic layer deposition (ALD).

A seed layer 30 may be deposited on the barrier layer 28. In one non-limiting example, the seed layer may be a copper seed layer. As another non-limiting example, the seed layer may be a copper alloy seed layer, such as copper manganese, copper cobalt, or copper nickel alloys. In the case of depositing copper in a feature, there are several exemplary options for the seed layer. First, the seed layer may be a PVD copper seed layer. The seed layer may also be formed by using other deposition techniques, such as CVD or ALD.

Second, the seed layer may be a stack film, for example, a liner layer and a PVD seed layer. A liner layer is a material used in between a barrier and a PVD seed to mitigate discontinuous seed issues and improve adhesion of the PVD seed. Liners are typically noble metals such as ruthenium (Ru), platinum (Pt), palladium (Pd), and osmium (Os), but the list may also include cobalt (Co) and nickel (Ni). Currently, CVD Ru and CVD Co are common liners; however, liner layers may also be formed by using other deposition techniques, such as ALD or PVD.

Third, the seed layer may be a secondary seed layer. A secondary seed layer is similar to a liner layer in that the secondary seed layer is typically formed from noble metals such as Ru, Pt, Pd, and Os, but the list may also include Co and Ni, and most commonly CVD Ru and CVD Co. (Like seed and liner layers, secondary seed layers may also be formed by using other deposition techniques, such as ALD or PVD.) The difference is that the secondary seed layer serves as the seed layer, whereas the liner layer is an intermediate layer between the barrier layer and the PVD seed.

After a seed layer has been deposited according to one of the examples described above, the feature may include a seed layer enhancement (SLE) layer, which is a thin layer of deposited metal, for example, copper having a thickness of about 2 nm. An SLE layer is also known as an electrochemically deposited seed (or ECD seed), which may be a conformally deposited layer.

An ECD copper seed is typically deposited using a basic chemistry that includes a very dilute copper ethylenediamine (EDA) complex. ECD copper seed may also be deposited using other copper complexes, such as citrate, tartrate, urea, etc., and may be deposited in a pH range of about 2 to about 11, about 3 to about 10, or in a pH range of about 4 to about 10. (For a more detailed discussion of ECD seed, see discussion of FIGS. 4-6 below.)

After a seed layer has been deposited according to one of the examples described above (which may also include an optional ECD seed), conventional ECD fill and cap may be performed in the feature, for example, using an acid deposition chemistry. Conventional ECD copper acid chemistry may include, for example, copper sulfate, sulfuric acid, methane sulfonic acid, hydrochloric acid, and organic additives (such as accelerators, suppressors, and levelers). Accelerator is used to enhance the plating rate inside the feature, the suppressor to suppress plating on field, and the leveler to reduce the thickness variation of the plated copper over small dense features and wide ones. The combination of these additives enhances the bottom-up plating inside the feature relative to the plating on field. This is called a bottom-up gap fill, super-fill, or super-conformal plating and can result in substantially void free fill.

Electrochemical deposition of copper has been found to be the most cost effective manner for depositing a copper metallization layer. In addition to being economically viable, ECD deposition techniques provide a substantially bottom up (e.g., nonconformal or superconformal) metal fill that is mechanically and electrically suitable for interconnect structures. However, the metallization layer may also be deposited electrolessly.

The barrier layer may be conventional barrier layer. As mentioned above, conventional barrier layers are typically made of refractory metals or refractory compounds, for example, titanium (Ti), tantalum (Ta), titanium nitride (TiN), tantalum nitride (TaN), etc. A conventional barrier layer is typically formed using a deposition technique called physical vapor deposition (PVD). The PVD technique is intrinsically limited into its step coverage, and therefore generally deposits a relatively thick layer (e.g., about 6 nm) to form a conformal and continuous barrier. Because of the thickness of the barrier layer, the integrity of a PVD-TaN/Ta barrier layer is expected to reach its limit at a feature diameter of about 30 nm.

Other barrier layers that have been explored in recent years as viable alternatives to traditional barrier layers include manganese-based barrier layers. For example, suitable barrier layers may include manganese (Mn) and manganese nitride (MnN). Manganese-based barrier layers can be deposited using CVD and ALD deposition techniques. Manganese-based barrier layers may be conformal. As a non-limiting example, a CVD-Mn barrier layer can be formed with a thickness in the range of about 1 to about 3 nm. Such a thickness range appears to have similar barrier properties as an approximate 6 nm PVD-TaN/Ta barrier layer. A thinner barrier layer in small features allows for less cladding, resulting in more volume for interconnect metal fill to improve device performance.

Manganese-based barrier layers 28 can form a unique layer when deposited on silicon (see FIG. 1). In that regard, the manganese-based barrier layer tends to form a thin self-formed MnSixOy diffusion barrier 28 (e.g., MnSiO3) at the surface of the dielectric layer without significant impact on the dielectric constant of the dielectric layer. The self-forming nature of this diffusion barrier layer 28 is the result of chemical interaction between the deposited manganese and the dielectric layer.

The growth of an MnSixOy layer creates a diffusion barrier layer having minimal thickness. Therefore, a thick manganese-based barrier on a silica dielectric surface forms a conformal, amorphous manganese silicate layer that acts as a barrier to copper (or other metal) diffusion into the dielectric film. To further reduce the thickness of the barrier layer, all of the deposited manganese-based barrier layer may be fully incorporated into the silicate.

In a typical process, a thin seed layer 30 is used over the barrier layer 28 as a seed for electroplating a metal interconnect 32 (see FIG. 2), typically in the range of between about 10 angstroms and about 600 angstroms. As discussed above, a seed layer may be formed using any of PVD, CVD, or ALD techniques. As a non-limiting example, the seed layer is a PVD copper layer, creating a stack layer of a manganese-based barrier layer and a copper layer. As another non-limiting example, the seed layer is a stack film of a cobalt or ruthenium liner layer and a PVD copper layer. As another non-limiting example, the seed layer is a secondary seed layer formed from either cobalt or ruthenium.

One problem with a manganese-based barrier layer is that manganese tends to dissolve in a conventional ECD acid plating bath subsequently used for depositing metallization after the seed layer deposition (see SEM image in FIG. 10). Therefore, a sufficiently thick and continuous copper seed layer is needed to prevent the manganese-based barrier layer from dissolving in the conventional ECD acid plating bath. In experimental testing in a conventional acid bath, a blanket layer, for example, approximately 180 angstroms of copper seed layer is needed to protect the manganese-based barrier layer from dissolution. In an alkaline bath, approximately 120 angstroms of copper seed is needed to protect the manganese-based barrier layer from dissolution. This problem is not limited to manganese-based barrier layers and extends to any highly reactive barrier layers.

Although a thick copper seed can help prevent dissolution of the manganese-based barrier layer, a thin copper seed layer, for example, less than 100 angstroms, is more advantageous in a stack film with an ALD or a CVD manganese-based barrier layer. In that regard, a thin copper seed layer allows for a greater opening at the mouth of the trench or via to aid in preventing potential pinch off at the opening.

Because of the dissolution tendencies of the manganese-based barrier layer, electrochemically depositing a metallization layer on a thin copper seed over a manganese-based barrier layer presents a technical challenge. In that regard, manganese has a negative standard electrode potential (E0=−1.18 V) and high reactivity; therefore, the manganese-based barrier layer and the copper seed stack film is prone to dissolving in the ECD acid plating bath.

Although not wishing to be bound by theory, the inventors hypothesize that for the dissolution of the manganese-based barrier layer in the ECD acid plating bath is that the contact between manganese and copper changes the electrochemical potential of Cu/Cu+2 from 0.3419 V to a more negative potential. The magnitude of that shift is dependent on the thickness of the manganese-based barrier layer. In that regard, the capacity of electron capturing by the copper seed layer is thickness dependent because, for a thin copper seed, there are only few monolayers of copper seed over the manganese-based barrier layer.

Another hypothesis is that the thin copper seed layer may be discountinuous, having breaks or holes that allow an opportunity for galvanic corrosion and dissolution of the manganese based barrier layer.

Because the films are only few monolayers thick, any dissolution of the copper and manganese stack film causes rapid degradation of the manganese-based barrier layer and may even result in a complete removal of the barrier layer. With dissolution of any portion of the barrier layer, the integrity of the microfeature workpiece is compromised.

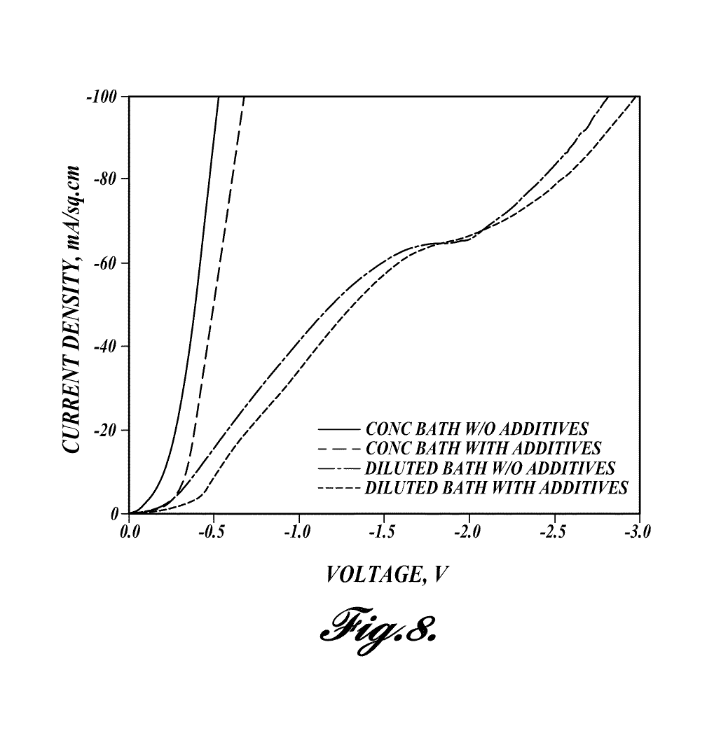

To reduce dissolution of the barrier layer, alternative approaches for electrochemically plating are discussed below. In general, low current density may help at the beginning of the plating process to reduce the possibility of rapid plating, which tends to cause pinch off at the mouth of the feature. On the other hand, high electrical potential may help decrease manganese dissolution as electrical potential increases, as shown in the attached corrosion diagram for a Cu/MnN stack film in FIG. 7. Therefore, voltage control with low current at entry can control initial plating and reduce manganese dissolution.

As a first approach, copper can be electrochemically plated in a diluted acid bath. The acid plating bath composition is typically 40 g/l Cu, 10-100 g/l sulfuric acid, and 50-100 ppm HCl. However, variations on these concentrations are common. As a non-limiting example, the concentration of a diluted ECD acid bath includes is between about 0.6 g/l and about 15 g/l Cu, or between about 1 g/l and about 10 g/l sulfuric acid, and between about 5 ppm and about 50 ppm HCl. A suitable pH for the plating chemistry may be in the range of about 1 to about 3, or about 1 to about 5.

The advantageous effect of electrochemically depositing copper in diluted acid bath is reduction of the dissolution of barrier layer and seed layer stack. Referring to the comparative graph in FIG. 8, voltage versus current density is provided for various baths: conventional concentrated ECD copper acid chemistry without additives and with additives, and diluted ECD copper acid chemistry without additive and with additives. As can be seen in FIG. 8, in a diluted ECD copper acid bath (as compared to the conventional ECD acid bath), there is a higher electrical potential (voltage) for a given current density. The result is controlled plating and reduced or substantially no manganese dissolution in the diluted ECD copper acid bath as compared to the conventional ECD copper acid bath.

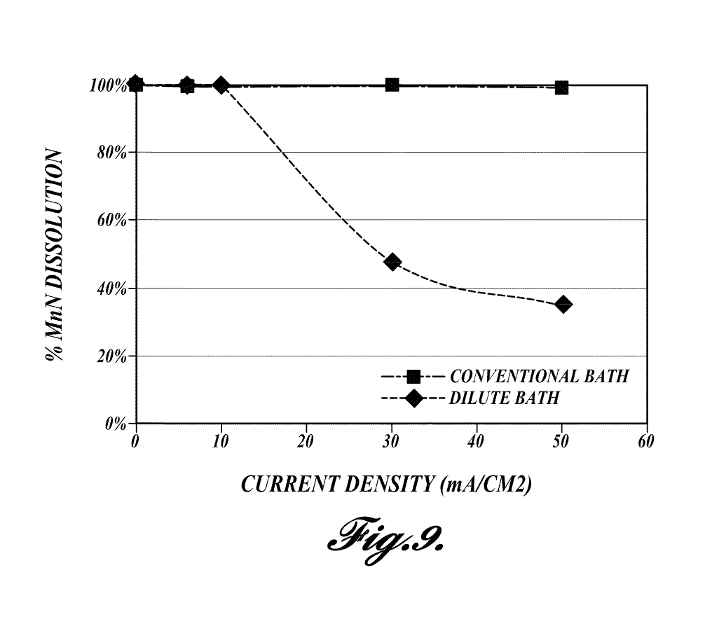

Referring to the comparative graph in FIG. 9, MnN dissolution versus current density is provided for conventional ECD copper acid chemistry and dilute ECD copper acid chemistry. As can be seen in FIG. 9, in a dilute ECD copper acid bath, dissolution is shown to be reduced for increasing current density. In contrast, in FIG. 9 in a conventional ECD copper acid bath, little to no reduction in MnN dissolution is achieved for increasing current density.

As a non-limiting example, an electrical potential in a range between −0.9 to −4 volts substantially reduces the dissolution of Cu/MnN during ECD copper plating. For example, plating copper at a current density of 10 mA/cm2 in a diluted solution produced a potential of −0.9 V between the anode and the cathode. Comparatively, a similar potential of −0.9 V is produced when Cu plated at 30 mA/cm2 in a conventional high acid chemistry. As another non-limiting example in accordance with embodiments of the present disclosure, the electrical potential may be in a range between −0.5 to −4 volts.

Another advantageous effect of using a diluted acid chemistry is that a diluted chemistry reduces the plating rate and thus can reduce the opportunity for pinch-off to occur when the plating growth at the mouth of the feature is faster than at the bottom-up fill rate.

As a second approach to reducing dissolution of the manganese-based barrier layer includes electrochemically depositing copper in a diluted basic chemistry, for example, ECD seed chemistry (discussed above). With reference to FIGS. 4-6, a process for forming an exemplary copper interconnect 120 will now be described. In this example, the formation of the dielectric layer 122, barrier layer 128, and seed layer 130 is identical to the process shown and described with reference to FIGS. 1-3. However, the formation of the copper interconnect 120 is according to a different process, as shown in FIGS. 4-6.

Plating at basic pH usually occurs at high potential in the range of about −1.5 to about −4 V, which is beneficial for reducing the dissolution of the manganese-based barrier layer. A suitable current density for electroplating may be in the range of about 1 mA/cm2 to about 5 mA/cm2.

As a non-limiting example, a suitable plating chemistry may include CuSO4, complexing agent such ethylenediamine, glyciene, citrate, tartaric acid, etc., and a pH adjustor, such as tetramethyl-ammonium hydroxide and boric acid.

In one embodiment of the present disclosure, a suitable pH range may be in the range of about 6 to about 11, in one embodiment of the present disclosure in the range of about 8 to about 11, in one embodiment of the present disclosure about 8 to about 10, and in one embodiment of the present disclosure about 9.3.

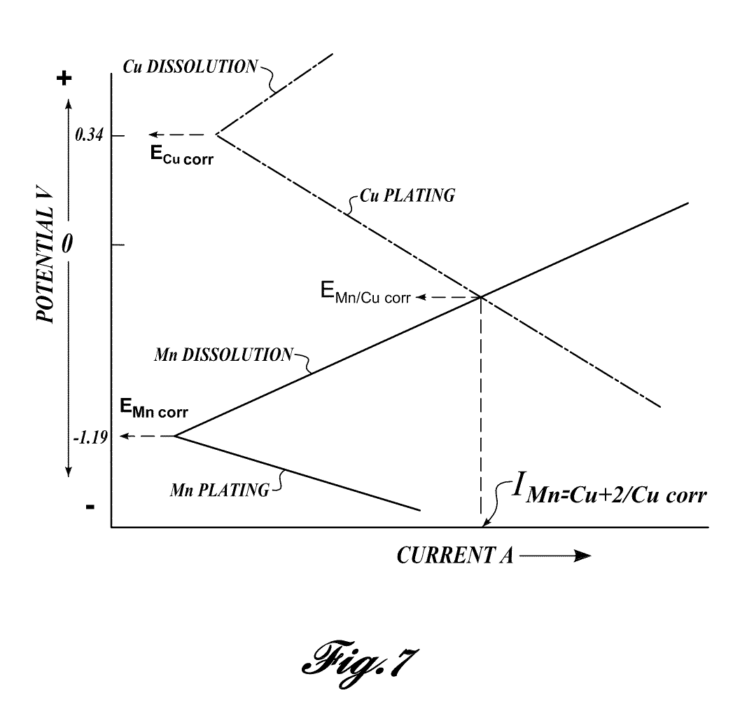

The deposition of copper in a basic chemistry occurs at high potential, for example in the range of −2 to −4. The high potential prevents dissolution of highly reactive films such as the manganese-based barrier layer. In some embodiments of the present disclosure, deposition may be followed by anneal to enhance the thermal reflow of copper into the feature (see, e.g., FIG. 5). The reflow of a conformal film enables the formation of reliable interconnects for sub-30 nm technology.

Although the technology is described herein using manganese-based barrier layer materials, in practice, this technology is applicable to any combination of films where at least one of those films has an electrochemical potential, E0, smaller than that of Cu (E0=0.34V), smaller than 0 V, or smaller than −0.25 V. Other non-limiting examples may include but are not limited to Ni (E0=−0.26 V), Ti (E0=−1.37 V), Co (E0=−0.28 V), Fe (E0=−0.44 V), Cr (E0=−0.41 V), Zn (E0=−0.76 V), etc.

### Example 1

### Conventional Acid Chemistry

Using a conventional ECD acid plating bath, the SEM image in FIG. 10 showed dissolution of the manganese based barrier layer. The plating bath included CuSO4 40 gm/liter, H2SO4 30 gml/liter, HCl 50 ppm, and accelerator, suppressor and leveler additives (6 ml/l, 7 ml/l, and 5 ml/l). Current density for plating was 9 mA/cm2.

### Example 2

### Diluted Acid Chemistry

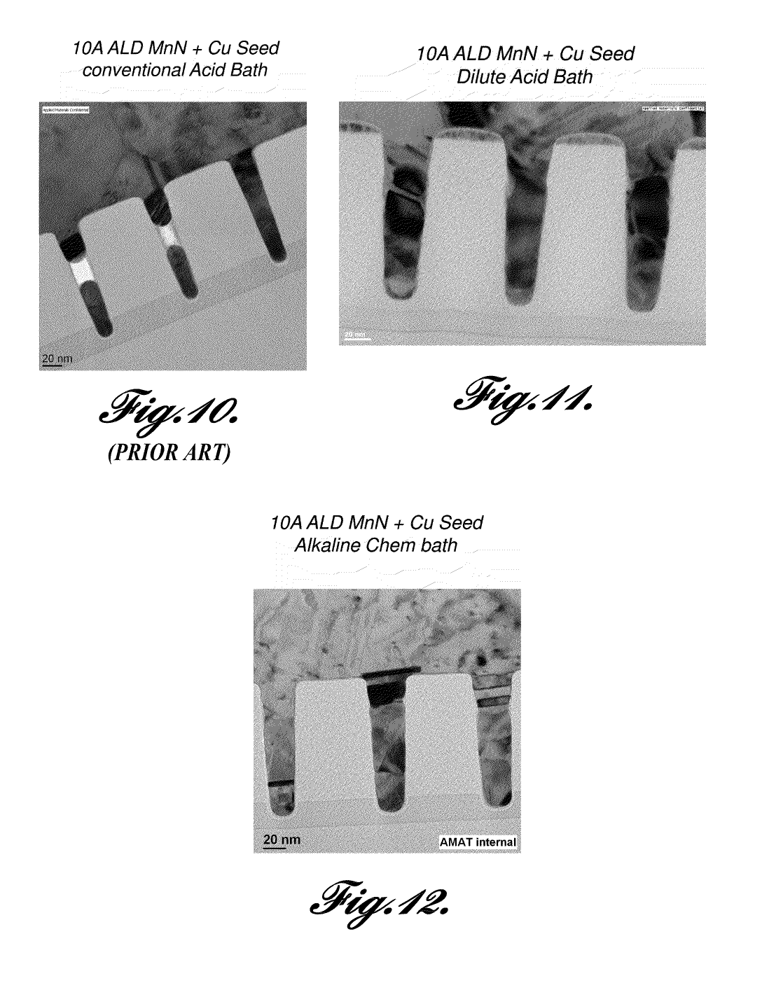

Using a diluted acid plating bath, the SEM image in FIG. 11 showed little to no dissolution of the manganese based barrier layer. The plating bath included CuSO4 5 gm/liter, H2SO4 1 gml/liter, HCl 8 ppm, and accelerator, suppressor and leveler additives (3 ml/l, 2 ml/l, and 0.5 ml/l). Current density for plating was 20-30 mA/cm2.

### Example 3

### Alkaline Chemistry

Using a diluted acid plating bath, the SEM image in FIG. 11 showed little to no dissolution of the manganese based barrier layer. The plating bath included Cu EDA 4 mM, pH 9.3. Current density for plating was 1 mA/cm2.

While illustrative embodiments have been illustrated and described, various changes can be made therein without departing from the spirit and scope of the disclosure.

1. A method for depositing metal on a reactive metal film on a workpiece, the method comprising:
electrochemically depositing a metallization layer on a seed layer formed on a workpiece using an electrolyte bath having at least one plating metal ion, a pH range of about 6 to about 11, and a current density in the range of about 1 mA/cm2 to about 5 mA/cm2, wherein the workpiece includes a barrier layer disposed between the seed layer and a dielectric surface of the workpiece, wherein the barrier and seed stack include at least one metal having a standard electrode potential of less than 0.34 V.

2. The method of claim 1, wherein the electrical potential of the workpiece during deposition of the metallization layer is in the range of about −0.5 V to about 4 V.

3. The method of claim 1, wherein the barrier and seed stack includes at least one metal having a standard electrode potential of less than 0 V.

4. The method of claim 1, wherein the barrier and seed stack includes at least one metal having a standard electrode potential of less than −0.25 V.

5. The method of claim 1, wherein the barrier layer includes manganese.

6. The method of claim 1, wherein the barrier layer is formed by depositing a compound selected from the group consisting of manganese and manganese nitride on a silicon oxide layer.

7. The method of claim 1, wherein the barrier layer is a manganese silicate layer.

8. The method of claim 1, wherein one compound that makes up the barrier layer is deposited by chemical vapor deposition or atomic layer deposition.

9. The method of claim 1, wherein metal for the seed layer is selected from the group consisting of copper, cobalt, nickel, gold, silver, manganese, tin, aluminum, ruthenium, and alloys thereof.

10. The method of claim 1, wherein the seed layer is deposited by chemical vapor deposition, physical vapor deposition, or atomic layer deposition.

11. The method of claim 1, wherein metal for the metallization layer is selected from the group consisting of copper, cobalt, nickel, gold, silver, manganese, tin, aluminum, and alloys thereof.

12. The method of claim 1, wherein the metallization layer is deposited electrochemically.

13. The method of claim 1, wherein the metallization layer is deposited electrolessly.

14. The method of claim 1, wherein the seed layer is a metal seed layer deposited using a chemistry including at least one metal complex selected from the group consisting of ethylenediamine, citrate, tartrate, and urea.

15. A method for depositing metal on a reactive metal film on a workpiece, the method comprising:
electrochemically depositing a metallization layer on a seed layer formed on a workpiece using an electrolyte bath having at least one plating metal ion, a pH range of about 6 to about 11, and a current density in the range of about 1 mA/cm2 to about 5 mA/cm2, wherein the workpiece includes a barrier layer disposed between the seed layer and a dielectric surface of the workpiece, wherein the barrier and seed stack include at least one metal having a standard electrode potential of less than −0.25 V.

16-18. (canceled)
